(19) United States
(12) Patent Application Publication
(10) Pub. No.: US 2025/0317669 A1
(43) Pub. Date: Oct. 9, 2025

(54) IMAGE SENSOR AND SEMICONDUCTOR DEVICE INCLUDING CAPACITOR STRUCTURE

(71) Applicant: SAMSUNG ELECTRONICS CO., LTD., Suwon-si (KR)

(72) Inventors: Chan Min Park, Suwon-si (KR); Kyung Hoon Kim, Suwon-si (KR); Sang Woo Kim, Suwon-si (KR)

(21) Appl. No.: 19/094,249

(22) Filed: Mar. 28, 2025

(30) Foreign Application Priority Data
Apr. 5, 2024 (KR) 10-2024-0046506

(51) Int. Cl. H04N 25/78; H10F 39/00

(52) U.S. Cl. CPC H04N 25/78; H10F 39/8037; H10F 39/811

(57) ABSTRACT

Disclosed are an image sensor and a semiconductor device with improved performance and reliability. The image sensor includes a pixel; and a comparator circuit configured to generate a comparison signal based on a ramp signal and a pixel signal received from the pixel, wherein the comparator circuit includes: a comparator including a first input node receiving the ramp signal and the pixel signal and a second input node receiving a reference signal; a first capacitor connected to the first input node; and a second capacitor connected to the second input node, wherein the first capacitor is closer to the comparator than the second capacitor is.

### CROSS-REFERENCE TO RELATED APPLICATION

This application claims priority from Korean Patent Application No. 10-2024-0046506 filed on Apr. 5, 2024 in the Korean Intellectual Property Office, and all the benefits accruing therefrom under 35 U.S.C. 119, the contents of which in its entirety are herein incorporated by reference.

### BACKGROUND

Image sensing devices can convert optical information into an electrical signal. An image sensing device may include a CCD (charge-coupled device) based image sensing device and a CMOS (complementary metal-oxide semiconductor) based image sensing device.

A CMOS image sensor may be abbreviated as CIS (CMOS image sensor). The CIS may include a plurality of pixels, e.g., two-dimensionally arranged pixels. Each of the pixels may include, for example, a photodiode (PD). The photodiode may serve to convert incident light into an electrical signal.

Recently, with the development of computer industry and communication industry, demand for image sensors with improved performance has increased in various fields, such as digital cameras, camcorders, smartphones, game devices, security cameras, medical micro cameras, and robots.

### SUMMARY

In some implementations, the present disclosure provides a semiconductor device, e.g., an image sensor with improved performance and reliability.

In a first general aspect, an image sensor includes: a pixel; and a comparator circuit configured to generate a comparison signal based on a ramp signal and a pixel signal received from the pixel, wherein the comparator circuit includes: a comparator including a first input node receiving the ramp signal and the pixel signal and a second input node receiving a reference signal; a first capacitor connected to the first input node; and a second capacitor connected to the second input node, wherein a distance from the first capacitor to the comparator is shorter than a distance from the second capacitor to the comparator in a first direction in a layout in a plan view.

In a second general aspect, semiconductor device includes: a pixel array structure in which a plurality of pixels are arranged; and a first capacitor structure configured to generate a comparison signal based on a first signal and a second signal received from the pixels. The first capacitor structure includes: a comparator configured to receive the first and second signals via a first input node, and to receive a third signal different from the first and second signals via a second input node; a first sampling capacitor connected to the first input node; a second sampling capacitor connected to the second input node; a first capacitor connected to a first node between the first sampling capacitor and the first input node; and a second capacitor connected to a second node between the second sampling capacitor and the second input node, wherein a capacitance of the first capacitor is different from a capacitance of the second capacitor.

In a third general aspect, an image sensor includes: a pixel array in which a plurality of pixels are arranged; and a comparator circuit structure including a plurality of capacitor circuits electrically connected to the pixel array. The plurality of capacitor circuits include first and second capacitor circuits configured to respectively receive first and second pixel signals from the pixel array, wherein the first capacitor circuit includes: a first comparator circuit configured to receive a ramp signal and the first pixel signal via a first input node thereof, and to receive a first reference signal via a second input node thereof; a first sampling capacitor connected to the first input node; and a second sampling capacitor connected to the second input node, wherein a distance from the first input node of the first comparator circuit to the first sampling capacitor in a first direction in a layout in a plan view is shorter than a distance from the second input node of the first comparator circuit to the second sampling capacitor in the first direction in the layout in the plan view, wherein the second capacitor circuit includes: a second comparator circuit configured to receive the ramp signal and the second pixel signal via a third input node thereof, and to receive a second reference signal via a fourth input node thereof; a third sampling capacitor connected to the third input node; and a fourth sampling capacitor connected to the fourth input node, wherein a distance from the third input node of the second comparator circuit to the third sampling capacitor in the first direction in the layout in the plan view is shorter than a distance from the fourth input node of the second comparator circuit to the fourth sampling capacitor in the first direction in the layout in the plan view.

Specific details of other embodiments are included in detailed descriptions and drawings.

### BRIEF DESCRIPTION OF DRAWINGS

FIG. 1 is a block diagram showing an example of an image sensor.

FIG. 2 is a diagram showing an example of a schematic layout of an image sensor.

FIG. 3 is a circuit diagram of an example of a pixel included in an image sensor.

FIG. 4 is a circuit diagram of an example of a comparator circuit included in an image sensor.

FIG. 5 is a diagram of an example of a comparator of a comparator circuit.

FIG. 6 is a layout diagram of an example of a capacitor structure.

FIG. 7 is a plan view showing an example of a capacitor structure.

FIG. 8 is a plan view showing an example of a capacitor structure.

FIG. 9 is a cross-sectional view showing an example of a capacitor structure.

FIG. 10 is a cross-sectional view showing an example of a capacitor structure.

FIG. 11 is a diagram showing an example of a schematic layout of an image sensor.

### DETAILED DESCRIPTIONS

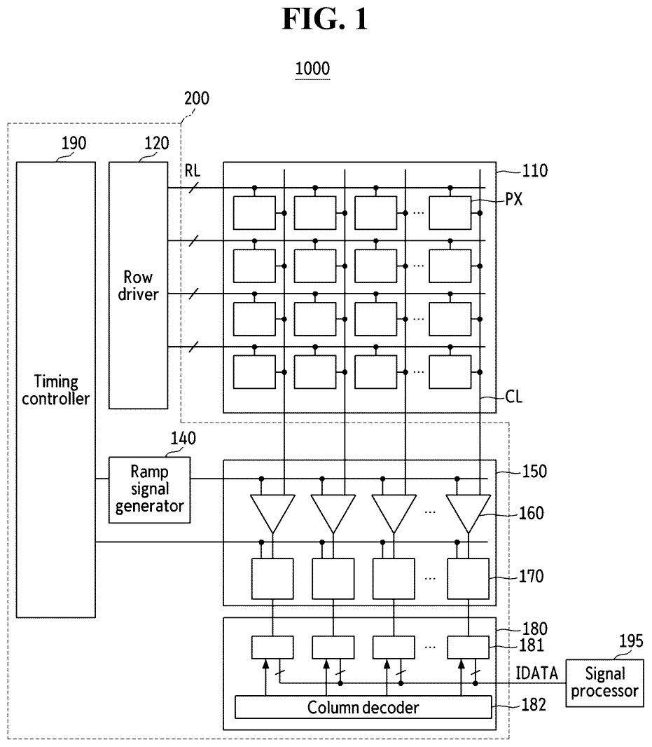

Hereinafter, the present disclosure will be described in more detail with reference to the attached drawings according to some examples of the present disclosure. Referring to FIGS. 1 to 7, an example of an image sensor will be described.

FIG. 1 is a block diagram showing an example of an image sensor.

An image sensor 1000 may be mounted in an electronic device having an imaging or light sensing function. For example, the image sensor 1000 may be mounted in an electronic device such as a camera, a smartphone, a wearable device, Internet of Things (IoT), a tablet PC (Personal Computer), PDA (Personal Digital Assistant), PMP (portable multimedia player) or a navigation device.

Additionally, the image sensor 1000 may be mounted in the electronic device that is embodied as a component in a vehicle, furniture, a manufacturing facility, a door, and various measuring devices.

The image sensor 1000 includes a pixel array 110, a row driver 120, a ramp signal generator 140, an analog-to-digital conversion circuit 150 (hereinafter referred to as an ADC circuit), a data output circuit 180, and a timing controller 190. The image sensor 1000 may further include a signal processor 195.

The pixel array 110 may include a plurality of row lines RL, a plurality of column lines CL, and a plurality of pixels PX respectively connected to the plurality of row lines RL and the plurality of column lines CL. The pixel array 110 may be arranged in rows and columns.

Each of the plurality of pixels PX may include at least one photoelectric conversion element. The pixel PX may detect light using the photoelectric conversion element and output an image signal as an electrical signal based on the detected light. For example, the photoelectric conversion element may include a photo diode, a photo transistor, a photo gate, or a pinned photodiode.

Each of the plurality of pixels PX may detect light in a specific spectral region. For example, the plurality of pixels PX may include a red pixel for converting light in the red spectrum region into an electrical signal, a green pixel for converting light in the green spectrum region into an electrical signal, and a blue pixel for converting light in the blue spectrum region into an electrical signal. In another example, the plurality of pixels may include pixels of combinations of different colors, for example, a yellow pixel, a cyan pixel, and a green pixel. However, the subject matter of the present disclosure is not limited thereto.

A color filter array may be disposed on top of the plurality of pixels PX and be configured to transmit light of a specific spectral region therethrough. A color that may be detected by each of the plurality of pixels may be determined based on the color filter disposed on top of each of the plurality of pixels. However, the subject matter of the present disclosure is not limited thereto, and in a specific photoelectric conversion element, light in a specific wavelength band may be converted into an electrical signal depending on a level of an electrical signal applied to the photoelectric conversion element.

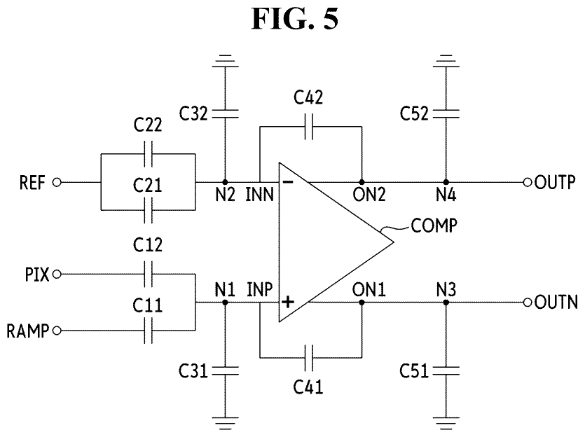

The row driver 120 may drive the pixel array 110 on a row basis. The row driver 120 may decode a row control signal (e.g., an address signal) received from the timing controller 190 and may select at least row line from among the row lines constituting the pixel array 110 in response to the decoded row control signal. For example, the row driver 120 may generate a selection signal to select one of a plurality of rows. Additionally, the pixel array 110 may output a pixel signal, for example, a pixel signal (PIX in FIG. 5) from a row selected based on the selection signal provided from the row driver 120.

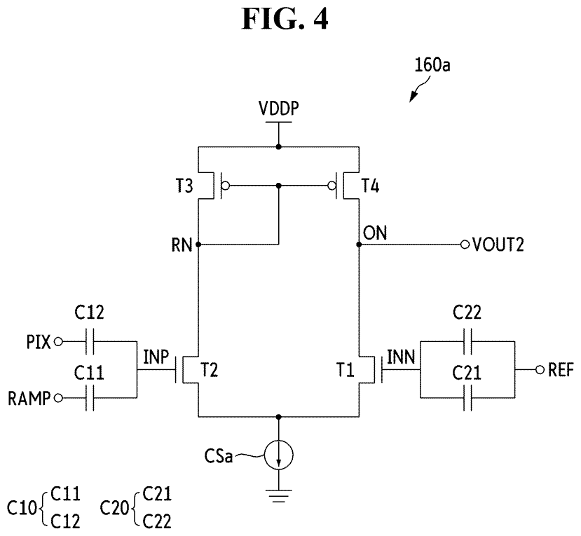

The row driver 120 may transmit control signals for output of the pixel signal (PIX in FIG. 4 and FIG. 5) to the pixel array 110, and the pixel PX may operate in response to the control signals, thereby outputting the pixel signal (PIX in FIG. 4 and FIG. 5).

Although not specifically shown, a reference signal generator (not shown) may generate a reference signal (REF in FIGS. 4 and 5) under control of the timing controller 190. The reference signal generator (not shown) may generate a fixed voltage or current. However, the subject matter of the present disclosure is not limited thereto.

The ramp signal generator 140 may generate a ramp signal (RAMP in FIGS. 4 and 5), a level of which rises or falls at a predetermined slope under the control of the timing controller 190. The ramp signal (RAMP in FIG. 4 and FIG. 5) may be provided to each of a plurality of comparator circuits 160 provided in the ADC circuit 150.

The ADC circuit 150 may include the plurality of comparator circuits 160 and a plurality of counter circuits 170. The ADC circuit 150 may convert the pixel signal (PIX in FIGS. 4 and 5) input from the pixel array 110 into a pixel value as a digital signal. The ADC circuit 150 may perform correlated double sampling (CDS) as one example of a noise removal method. Each pixel signal (PIX in FIG. 4 and FIG. 5) received through each of the plurality of column lines CL may be converted into the pixel value as a digital signal, by the comparator circuit 160 and the counter circuit 170.

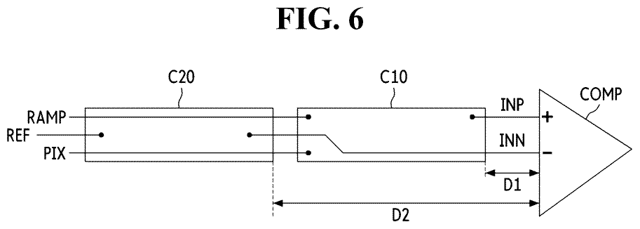

The comparator circuit 160 may output a comparison result obtained by comparing a difference between the ramp signal (RAMP in FIG. 4 and FIG. 5) and the pixel signal RAMP in FIG. 4 and FIG. 5 with the reference signal (REF in FIG. 5 and FIG. 6), based on the pixel signal (PIX in FIG. 4 and FIG. 5) and the ramp signal (RAMP in FIG. 4 and FIG. 5). The comparator circuit 160 may be connected to the column line CL.

The comparator circuit 160 may include one or more comparators (COMP in FIG. 5). The comparator (COMP in FIG. 5) may be embodied, for example, as an OTA (Operational Transconductance Amplifier) or a differential amplifier. The comparator circuit 160 may be provided with an input terminal that receives the ramp signal (RAMP in FIG. 4 and FIG. 5), the pixel signal (PIX in FIG. 4 and FIG. 5), and the reference signal (REF in FIG. 4 and FIG. 5).

The counter circuit 170 may count a level transition point of a comparison signal output from the comparator circuit 160 and output a count value. The counter circuit 170 may include a latch circuit and an arithmetic circuit. The latch circuit may hold (latch) a digital value as a count result from the counter circuit 170.

The data output circuit 180 may temporarily store therein a pixel value output from the ADC circuit 150 and then output the pixel value. The data output circuit 180 may include a plurality of column memories 181 and a column decoder 182. The column memory 181 may store therein the pixel value received from the counter circuit 170. In some implementations, each of the plurality of column memories 181 may be disposed in the counter circuit 170. A plurality of pixel values stored in the plurality of column memories 181 may be output as image data IDTA under control of the column decoder 182.

The timing controller 190 may output a control signal to each of the row driver 120, the reference signal generator (not shown), the ramp signal generator 140, the ADC circuit 150, and the data output circuit 180 to control an operation or a timing of each of the row driver 120, the reference signal generator (not shown), the ramp signal generator 140, the ADC circuit 150, and the data output circuit 180.

The signal processor 195 may perform noise reduction processing, gain adjustment, waveform normalization processing, interpolation processing, white balance processing, gamma processing, edge emphasis processing, binning, etc. on the image data IDTA. However, the subject matter of the present disclosure is not limited thereto. In some implementations, the signal processor 195 may be disposed in a processor external to the image sensor 1000.

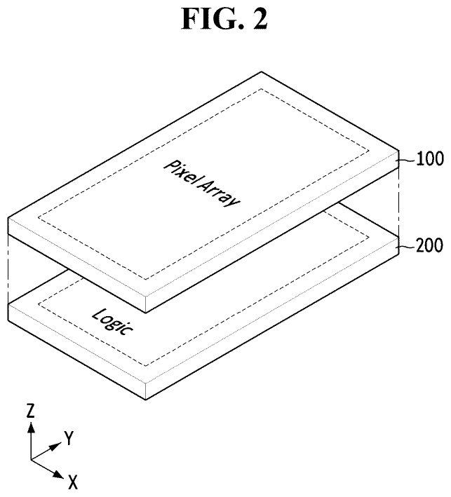

FIG. 2 is a diagram showing an example of a schematic layout of an image sensor.

Referring to FIG. 2, an image sensor includes a first substrate structure 100 and a second substrate structure 200 that are stacked.

In the first substrate structure 100, a plurality of pixels PX may be arranged in a two-dimensional array structure and may be disposed in a plane including a first direction X and a second direction Y. That is, the first substrate structure 100 may include a pixel array. The first direction X and the second direction Y may be perpendicular to each other.

The second substrate structure 200 may include a logic area Logic. The second substrate structure 200 may be disposed under the first substrate structure 100. The first substrate structure 100 and the second substrate structure 200 may be electrically connected to each other. The second substrate structure 200 may allow the pixel signal PIX transmitted from the first substrate structure 100 to be transmitted to the logic area of the second substrate structure 200.

Logic elements may be disposed in the logic area of the second substrate structure 200. The logic elements may include circuits for processing the pixel signal received from the plurality of pixels PX.

The first substrate structure 100 and the second substrate structure 200 may be stacked in a third direction Z. The third direction Z may be a direction perpendicular to the first direction X and the second direction Y.

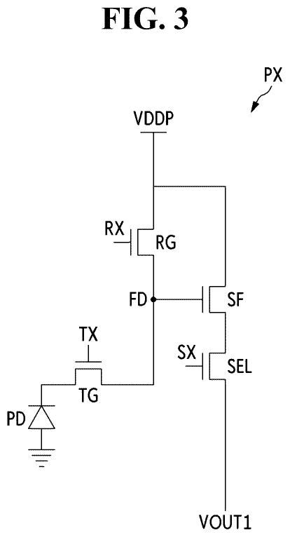

FIG. 3 is a circuit diagram of an example of a pixel included in an image sensor.

Referring to FIG. 3, each pixel PX includes a photoelectric conversion layer PD, a transfer transistor TG, a floating diffusion area FD, a reset transistor RG, a source follower transistor SF, and a select transistor SEL.

The photoelectric conversion layer PD may generate charges in proportion to an amount of light incident from an outside. The photoelectric conversion layer PD may be coupled to the transfer transistor TG that transfers the generated and accumulated charges to the floating diffusion area FD. The floating diffusion area FD is an area that converts the charges into voltage. Because the floating diffusion area FD has parasitic capacitance, the charges may be stored therein cumulatively.

One end of the transfer transistor TG may be connected to the photoelectric conversion layer PD, and the other end of the transfer transistor TG may be connected to the floating diffusion area FD. The transfer transistor TG may be embodied as a transistor operating under a predetermined bias (e.g., a transfer signal TX). That is, the transfer transistor TG may transfer the charges generated from the photoelectric conversion layer PD to the floating diffusion area FD in response to the transfer signal TX.

The source follower transistor SF may amplify change in an electrical potential of the floating diffusion area FD having received the charges from the photoelectric conversion layer PD and output the amplified change to a first output line VOUT1. When the source follower transistor SF is turned on, a predetermined electrical potential provided to a drain of the source follower transistor SF, for example, a power voltage VDDP may be transferred to a drain area of the select transistor SEL.

The select transistor SEL may select a unit pixel to be read on a row basis. The select transistor SEL may be embodied as a transistor driven by a selection line that applies a predetermined bias (e.g., a row selection signal SX) thereto.

The reset transistor RG may periodically reset the floating diffusion area FD. The reset transistor RG may be embodied as a transistor driven by a reset line that applies a predetermined bias (e.g., a reset signal RX) thereto. When the reset transistor RG is turned on based on the reset signal RX, a predetermined electrical potential provided to a drain of the reset transistor RG, for example, a power voltage VDD, may be transferred to the floating diffusion area FD.

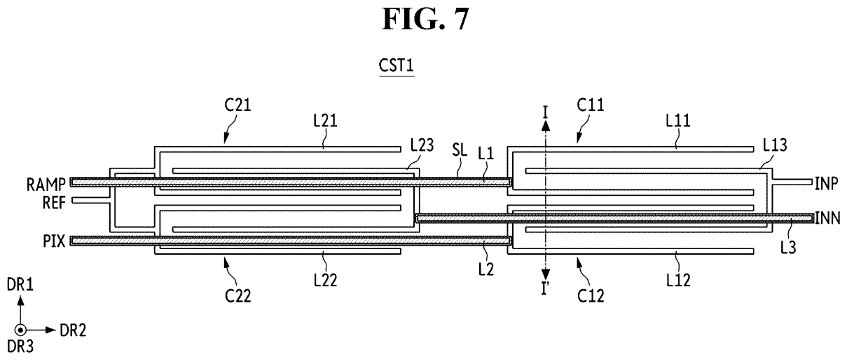

FIG. 4 is a circuit diagram of an example of a comparator circuit included in an image sensor. FIG. 5 is a diagram of an example of a comparator of a comparator circuit. FIG. 6 is a layout diagram of an example of a capacitor structure. FIG. 7 is a plan view, e.g., a top plan view, showing an example of a capacitor structure.

Referring to FIG. 4 and FIG. 5, a comparator circuit 160a includes a current source CSa, first to fourth transistors T1 to T4, a first capacitor C10, and a second capacitor C20. The comparator circuit 160a may refer to one of the plurality of comparator circuits 160 in FIG. 1.

The current source CSa may provide a bias current to operate the comparator circuit 160a. One end of each of the first and second transistors T1 and T2 may be connected to the current source CSa. Each of the first and second transistors T1 and T2 may be embodied as an NMOS transistor.

The first and second capacitors C10 and C20 may be respectively connected to gate terminals of the first and second transistors T1 and T2, that is, first and second input nodes INN and INP.

The first capacitor C10 may include a (1_1)-st capacitor C11 and a (1_2)-nd capacitor C12 connected in parallel with each other. The (1_1)-st capacitor C11 may have one end connected to the first input node INP and the other end receiving the ramp signal RAMP. The (1_2)-nd capacitor C12 may have one end connected to the first input node INP, and the other end receiving the pixel signal PIX.

Each of the (1_1)-st capacitor C11 and the (1_2)-nd capacitor C12 may be a sampling capacitor that stores charges therein.

The second capacitor C20 may include a (2_1)-st and a (2_2)-nd capacitors C21 and C22 connected in parallel with each other. Each of the (2_1)-st and (2_2)-nd capacitors C2 and C22 may have one end connected to the second input node INN, and the other end receiving the reference signal REF.

Each of the (2_1)-st and (2_2)-nd capacitors C21 and C22 may be a sampling capacitor that stores charges therein.

Each of the third and fourth transistors T3 and T4 may be embodied as a PMOS transistor. A power voltage VDDP may be applied to one end of each of the third and fourth transistors T3 and T4. The other end of the third transistor T3 may be connected to a comparison node RN, and the other end of the fourth transistor T4 may be connected to an output node ON and thus may be connected to a second output line VOUT2.

Referring to FIG. 4 and FIG. 5, the first input node INN may be a negative input terminal of the comparator COMP, and the second input node INP may be a positive input terminal of the comparator COMP.

The comparator circuit 160a may include a third capacitor C31 and a fourth capacitor C32.

One end of the third capacitor C31 may be connected to a first node N1 between the first capacitor C10 and the first input node INP, and the other end thereof may be connected to a ground. One end of the fourth capacitor C32 may be connected to a second node N2 between the second capacitor C20 and the second input node INN, and the other end thereof may be connected to the ground.

The comparator circuit 160a may include a fifth capacitor C41 and a sixth capacitor C42.

One end of the fifth capacitor C41 may be connected to the first input node INP, and the other end thereof may be connected to a third node ON1 between the first input node INP and a first output node OUTN of the comparator circuit 160a.

One end of the sixth capacitor C42 may be connected to the second input node INN, and the other end thereof may be connected to a fourth node ON2 between the second input node INN and a second output node OUTP of the comparator circuit 160a.

The comparator circuit 160a may include a seventh capacitor C51 and an eighth capacitor C52.

One end of the seventh capacitor C51 may be connected to a fifth node N3 between the first output node OUTN and the third node ON1, and the other end thereof may be connected to the ground. One end of the eighth capacitor C52 may be connected to a sixth node N4 between the second output node OUTP and the fourth node ON2, and the other end thereof may be connected to the ground.

Referring to FIG. 6, a distance D1 from the comparator COMP to the first capacitor C10 may be different from a distance D2 from the comparator COMP to the second capacitor C20. For example, the distance D1 from the comparator COMP to the first capacitor C10 may be smaller than the distance D2 from the comparator COMP to the second capacitor C20.

Specifically, the distance D1 from the first input node INP to the first capacitor C10 may be different from the distance D2 from the second input node INN to the second capacitor C20. For example, the distance D1 from the first input node INP to the first capacitor C10 may be smaller than the distance D2 from the second input node INN to the second capacitor C20.

Accordingly, a capacitance of the third capacitor (C31 in FIG. 5) may be different from that of the fourth capacitor (C32 in FIG. 5). For example, the capacitance of the third capacitor (C31 in FIG. 5) may be smaller than that of the fourth capacitor (C32 in FIG. 5).

Since the capacitor structure that does not require symmetry, for example, when three input signals REF, RAMP, and PIX are input to the comparator circuit, the sampling capacitor connected to the first input node INP of the comparator circuit may be positioned closer to the comparator circuit than the sampling capacitor connected to the second input node INN is. Accordingly, a parasitic capacitance adjacent to the first input node INP may be reduced.

Referring to FIG. 7, a first capacitor structure CST1 includes the (1_1)-st capacitor C11, the (1_2)-nd capacitor C12, the (2_1)-st capacitor C21, the (2_2)-nd capacitor C22, a (1_1)-st wiring line L11, a (1_2)-nd wiring line L12, a (1_3)-rd wiring line L13, a (2_1)-st wiring line L21, a (2_2)-nd wiring line L22, and a (2_3)-rd wiring line L23.

The first direction DR1 may refer to a direction in which the column lines CL are spaced apart from each other, and the second direction DR2 may refer to a direction in which the column line CL extends. The third direction DR3 may refer to a vertical direction perpendicular to the first and second directions DR1 and DR2.

The (1_1)-st capacitor C11 may include the (1_1)-st wiring line L11 and one portion of the (1_3)-rd wiring line L13. The (1_2)-nd capacitor C12 may include the (1_2)-nd wiring line L12 and the other portion of the (1_3)-rd wiring line L13. The (2_1)-st capacitor C21 may include the (2_1)-st wiring line L21 and one portion of the (2_3)-rd wiring line L23. The (2_2)-nd capacitor C22 may include the (2_2)-nd wiring line L22 and the other portion of the (2_3)-rd wiring line L23.

The ramp signal RAMP may be provided to the (1_1)-st capacitor C11 via a first connection line L1, and the pixel signal PIX may be provided to the (1_2)-nd capacitor C12 via a second connection line L2. Accordingly, the ramp signal and the pixel signal RAMP and PIX may be provided to the first input node INP.

The reference signal REF may be provided from the second capacitor C20 to the second input node INN via a third connection line L3.

Along the third direction DR3, the first and second connection lines L1 and L2 may be disposed on the second capacitor C20, and the third connection line L3 may be disposed on the first capacitor C10.

Along the third direction DR3, shielding layers SL may be respectively interposed between the first connection line L1 and the (2_1)-st capacitor C21, between the second connection line L2 and the (2_2)-nd capacitor C22, and the third connection between L3 and the (1_2)-nd capacitor C12.

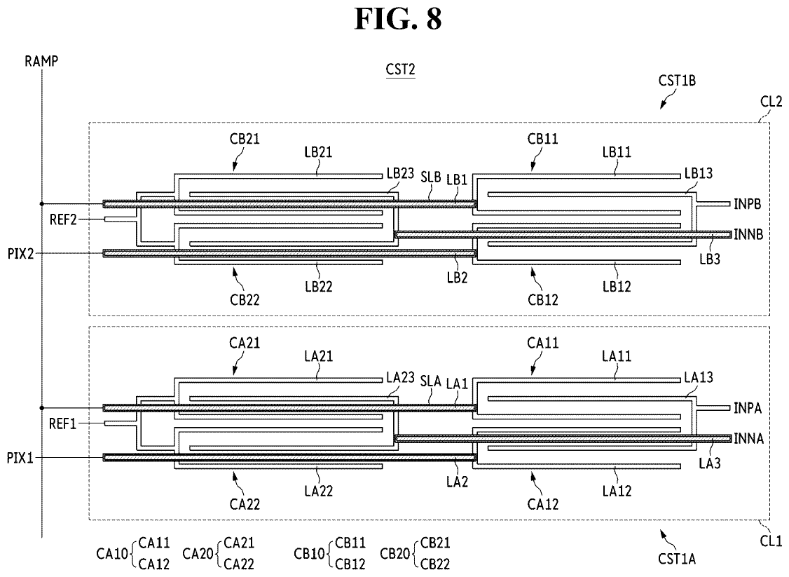

FIG. 8 is a plan view showing another example of a capacitor structure. To avoid redundant description, the description will focus on differences thereof from those described above in reference to FIGS. 1 to 7.

Referring to FIG. 8, a second capacitor structure CST2 includes a plurality of capacitor structures. For example, the second capacitor structure CST2 may include a 1A-th capacitor structure CST1A and a 1B-th capacitor CST1B that receive first and second pixel signals PIX1 and PIX2 from the pixel array (110 in FIG. 1), respectively.

The plurality of capacitor structures included in the second capacitor structure CST2 may be arranged in an array form. The number of capacitor structures included in the second capacitor structure CST2 is not limited to that shown in the drawing.

The first direction DR1 may refer to a direction in which first and second column lines CL1 and CL2 are spaced apart from each other, and the second direction DR2 may refer to a direction in which the first and second column lines CL1 and CL2 extend. The third direction DR3 may refer to a direction perpendicular to the first and second directions DR1 and DR2.

The 1A-th capacitor structure CST1A may include a first comparator circuit that receives the ramp signal RAMP and the first pixel signal PIX1 via a 1A-th input node INPA and receives a first reference signal REF1 via a 2A-th input node INNA, a 1A-th sampling capacitor CA10 connected to the 1A-th input node INPA, and a 2A-th sampling capacitor CA20 connected to the 2A-th input node INNA.

The 1A-th sampling capacitor CA10 may be disposed closer to the first comparator circuit than the 2A-th sampling capacitor CA20 may be. A distance from the 1A-th input node INPA to the 1A-th sampling capacitor CA10 may be smaller than a distance from the 2A-th input node INNA to the 2A-th sampling capacitor CA20.

The 1A-th sampling capacitor CA10 may include a (1_1A)-th sampling capacitor CA11 having one end connected to the 1A-th input node INPA, and the other end configured to receive the ramp signal RAMP, and a (1_2A)-th sampling capacitor CA12 having one end connected to the 1A-th input node INPA and the other end being configured to receive the first pixel signal PIX1.

The 2A-th sampling capacitor CA20 may include (2_1A)-th and (2_2A)-th sampling capacitors CA21 and CA22 connected in parallel with each other. One end of each of the (2_1A)-th and (2_2A)-th sampling capacitors CA21 and CA22 may be connected to the 2A-th input node INNA, and the other end thereof may receive the first reference signal REF1.

The 1A-th capacitor structure CST1A may include a (1_1A)-th wiring line LA11, a (1_2A)-th wiring line LA12, a (1_3A)-th wiring line LA13, a (2_1A)-th wiring line LA21, a (2_2A)-th wiring line LA22, and a (2_3A)-th wiring line LA23.

The (1_1A)-th capacitor CA11 may include the (1_1A)-th wiring line LA11 and one portion of the (1_3A)-th wiring line LA13. The (1_2A)-th capacitor CA12 may include the (1_2A)-th wiring line LA12 and the other portion of the (1_3A)-th wiring line LA13.

The (2_1A)-th capacitor CA21 may include the (2_1A)-th wiring line LA21 and one portion of the (2_3A)-th wiring line LA23. The (2_2A)-th capacitor CA22 may include the (2_2A)-th wiring line LA22 and the other portion of the (2_3A)-th wiring line LA23.

Along the third direction DR3, shielding layers SLA may be respectively disposed between a 1A-th connection line LA1 and the (2_1A)-th capacitor CA21, between a 2A-th connection line LA2 and the (2_2A)-th capacitor CA22, and between a 3A-th connection line LA3 and the (1_2A)-th capacitor CA12.

The 1B-th capacitor structure CST1B may include a second comparator circuit that receives the ramp signal RAMP and the second pixel signal PIX2 via a 1B-th input node INPB and receives a second reference signal REF2 via a 2B-th input node INNB, a 1B-th sampling capacitor CB10 connected to a 1B-th input node INPB, and a 2B-th sampling capacitor CB20 connected to the 2B-th input node INNB.

The 1B-th sampling capacitor CB10 may be disposed closer to the second comparator circuit than the 2B-th sampling capacitor CB20 may be. A distance from the 1B-th input node INPB to the 1B-th sampling capacitor CB10 may be smaller than a distance from the 2B-th input node INNB to the 2B-th sampling capacitor CB20.

The 1B-th sampling capacitor CB10 may include a (1_1B)-th sampling capacitor CB11 having one end connected to the 1B-th input node INPB, and the other end receiving the ramp signal RAMP, and a (1_2B)-th sampling capacitor CB12 having one end connected to the 1B-th input node INPB, and the other end receiving the second pixel signal PIX2.

The 2B-th sampling capacitor CB20 may include (2_1B)-th and (2_2B)-th sampling capacitors CB21 and CB22. One end of each of the (2_1B)-th and (2_2B)-th sampling capacitors CB21 and CB22 may be connected to a 2B-th input node INNB, and the other end thereof may receive the second reference signal REF2.

The 1B-th capacitor structure CST1B may include a (1_1B)-th wiring line LB11, a (1_2B)-th wiring line LB12, a (1_3B)-th wiring line LB13, a (2_1B)-th wiring line LB21, a (2_2B)-th wiring line LB22 and a (2_3B)-th wiring line LB23.

The (1_1B)-th capacitor CB11 may include the (1_1B)-th wiring line LB11 and one portion of the (1_3B)-th wiring line LB13, and the (1_2B)-th capacitor CB12 may include the (1_2B)-th wiring line LB12 and the other portion of the (1_3B)-th wiring line LA13. The (2_1B)-th capacitor CB21 may include the (2_1B)-th wiring line LB21 and one portion of the (2_3B)-th wiring line LB23, and the (2_2B)-th capacitor CB22 may include the (2_2B)-th wiring line LB22 and the other portion of the (2_3B)-th wiring line LB23.

Along the third direction DR3, shielding layers SLB may be respectively disposed between a 1B-th connection line LB1 and the (2_1B)-th capacitor CB21, between a 2B-th connection line LB2 and the (2_2B)-th capacitor CB22, and between a 3B-th line LB3 and the (1_2B)-th capacitor CB12.

The ramp signal RAMP may be provided to the (1_1A)-th capacitor CA11 via the 1A-th connection line LA1 and may be provided to the (1_1B)-th capacitor CB11 via the 1B-th connection line LB1.

The first pixel signal PIX1 may be provided to the (1_2A)-th capacitor CA12 via the 2A-th connection line LA2 and may be provided to the (1_2B)-th capacitor CB12 via the 2B-th connection line LB2.

Accordingly, the ramp signal RAMP may be provided to the 1A-th input node INPA and the 1B-th input node INPB. The first and second pixel signals PIX1 and PIX2 may be provided to the 1A-th input node INPA and the 1B-th input node INPB, respectively.

Each of the first and second reference signals REF1 and REF2 may be provided to the 2A-th input node INNA via the 3A-th connection line LA3, and to the 2B-th input node INNB via the 3B-th connection line LB3.

The 1A-th capacitor structure CST1A may be disposed in the first column line CL1. The 1B-th capacitor structure CST1B may be disposed in the second column line CL2. A pitch between the column lines (CL in FIG. 1) may be smaller than or equal to n times a pitch between the pixels (PX in FIG. 1) where n may be a positive rational number.

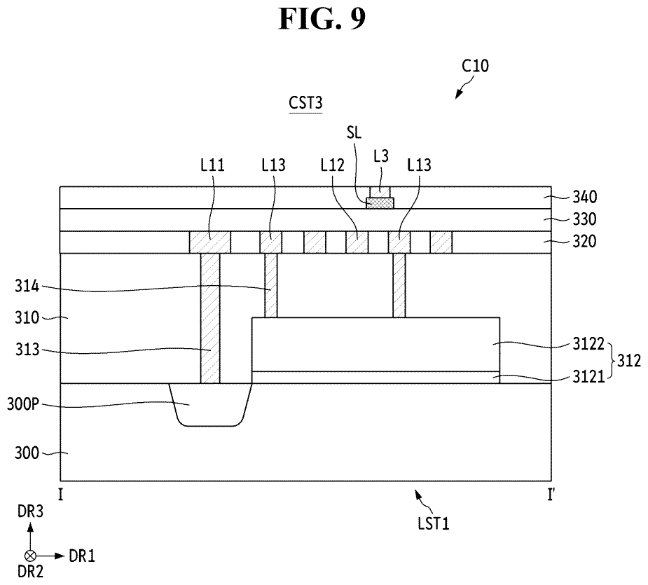

FIG. 9 is a cross-sectional view showing an example of a capacitor structure. For convenience of description, the description will focus on differences thereof from those described above using FIGS. 1 to 8. For reference, FIG. 9 is a cross-sectional view along a line I-I′ in FIG. 7.

Referring to FIG. 9, a third capacitor structure CST3 included a substrate 300 and a gate structure 312.

The substrate 300 may be a rigid substrate such as a substrate made of one or more semiconductor materials selected from the group consisting of Si, Ge, SiGe, GaP, GaAs, SiC, SiGeC, InAs, and InP, an SOI substrate, a quartz substrate, and a glass substrate for a display, or a flexible plastic substrate made of polyimide, polyethylene terephthalate (PET), polyethylene naphthalate (PEN), poly methyl methacrylate (PMMA), polycarbonate (PC), polyether sulfone (PES), or polyester. Other semiconductor elements may be disposed on the substrate 300. For example, the semiconductor elements may include, but are not limited to, transistors, resistors, or capacitors.

The gate structure 312 may include a gate insulating film 3121 and a gate electrode 3122.

The gate insulating film 3121 may be formed on the substrate 300. The gate insulating film 3121 may be disposed between the substrate 300 and the gate electrode 3122.

The gate insulating film 3121 may include silicon oxide or silicon nitride. For example, the gate insulating film 3121 may include SiON. However, the subject matter of the present disclosure is not limited thereto. Alternatively, the gate insulating film 3121 may include one or more of hafnium oxide, hafnium silicon oxide, lanthanum oxide, lanthanum aluminum oxide, zirconium oxide, zirconium silicon oxide, tantalum oxide, titanium oxide, aluminum oxide, lead scandium tantalum oxide, or lead zinc niobate. However, the subject matter of the present disclosure is not limited thereto. The gate insulating film 3121 may have a stack structure in which a plurality of films are sequentially stacked. In another example, another material film may be interposed between the substrate 300 and the gate insulating film 3121.

The gate electrode 3122 may be formed on the gate insulating film 3121. The gate electrode 3122 may be formed as a single layer or multiple layers including titanium (Ti), tantalum (Ta), aluminum (Al), tungsten (W), and alloys thereof. However, the subject matter of the present disclosure is not limited thereto.

An impurity area 300P may be formed within the substrate 300. The impurity area 300P may be formed on at least one side of the gate structure 312. For example, the impurity area 300P may include an n-type or p-type conductive material.

A first interlayer insulating film 310 may be formed to cover the substrate 300, the gate insulating film 3121, and the gate electrode 3122. For example, the first interlayer insulating film 310 may include silicon oxide. However, the subject matter of the present disclosure is not limited thereto.

Along the third direction DR3, a second interlayer insulating film 320, a third interlayer insulating film 330, and a fourth interlayer insulating film 340 may be sequentially stacked on the first interlayer insulating film 310. The second interlayer insulating film 320, the third interlayer insulating film 330, and the fourth interlayer insulating film 340 may include the same material as that of the first interlayer insulating film 310 or may include a different material from that of the first interlayer insulating film 310.

The (1_1)-st wiring line L11, the (1_2)-nd wiring line L12, and the (1_3)-rd wiring line L13 may be disposed within the second interlayer insulating film 320. The third connection line L3 may be disposed within the fourth interlayer insulating film 340.

Along the third direction DR3, the shielding layer SL may be spaced apart from the (1_1)-st wiring line L11, the (1_2)-nd wiring line L12, and the (1_3)-rd wiring line L13. Along the third direction DR3, the shielding layers SL may be respectively disposed between the (1_1)-st wiring line L11, the (1_2)-nd wiring line L12, and the (1_3)-rd wiring line L13 and the third connection line L3.

A first connection via 313 and a second connection via 314 may be formed within at least a portion of the first interlayer insulating film 310. The first connection via 313 and the second connection via 314 may extend through at least a portion of the first interlayer insulating film 310.

The first connection via 313 may electrically connect the impurity area 300P in the substrate 300 and the first capacitor C10 to each other. The second connection via 314 may electrically connect the gate electrode 3122 and the first capacitor C10 to each other.

Along the third direction DR3, the first capacitor C10 may be disposed on the gate structure 312.

Each of the (1_1)-st wiring line L11, the (1_2)-nd wiring line L12, the (1_3)-rd wiring line L13, the third connection line L3, the first connection via 313, and the second connection via 314 may include metal or metal nitride. However, the subject matter of the present disclosure is not limited thereto. For example, copper, tungsten, aluminum, ruthenium, platinum, titanium, and tantalum may be used as the metal, and tungsten nitride, tantalum nitride, or titanium nitride may be used as the metal nitride.

Referring to FIG. 9, the substrate 300, the gate insulating film 3121, and the gate electrode 3122 may constitute a first capacitor structure LST1. For example, the first capacitor structure may be a MOS capacitor. Furthermore, the wiring lines L11, L12, and L13 of the first capacitor C10 and the interlayer insulating film 320 may constitute a second capacitor structure. The second capacitor structure may constitute a vertical natural capacitor (VNCAP).

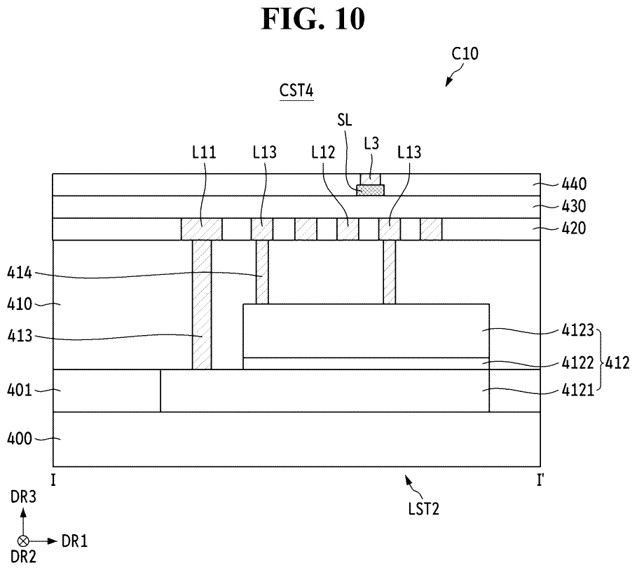

FIG. 10 is a cross-sectional view showing a capacitor structure according to some implementations. To avoid redundant description, the description will focus on differences thereof from those described above in relation to FIG. 9. For reference, FIG. 10 is a diagram corresponding to a cross-sectional view along a line I-I′ in FIG. 7.

Referring to FIG. 10, a fourth capacitor structure CST4 includes a substrate 400 and an electrode structure 412.

The substrate 400 may be a rigid substrate such as a substrate made of one or more semiconductor materials selected from the group consisting of Si, Ge, SiGe, GaP, GaAs, SiC, SiGeC, InAs, and InP, an SOI substrate, a quartz substrate, and a glass substrate for a display, or a flexible plastic substrate made of polyimide, polyethylene terephthalate (PET), polyethylene naphthalate (PEN), poly methyl methacrylate (PMMA), polycarbonate (PC), polyether sulfone (PES), or polyester. Other semiconductor elements may be disposed on the substrate 400. For example, the semiconductor elements may include, but are not limited to, transistors, resistors, or capacitors.

The electrode structure 412 may include a first electrode layer 4121, a second electrode layer 4123 on the first electrode layer 4121, and a dielectric layer 4122 between the first and second electrode layers 4121 and 4123.

A first interlayer insulating film 410 may be formed to cover the first interlayer insulating layer 401 and the electrode structure 412. For example, the first interlayer insulating film 410 may include silicon oxide. However, the subject matter of the present disclosure is not limited thereto.

Along the third direction DR3, a second interlayer insulating film 420, a third interlayer insulating film 430, and a fourth interlayer insulating film 440 may be sequentially stacked on the first interlayer insulating film 410. The second interlayer insulating film 420, the third interlayer insulating film 430, and the fourth interlayer insulating film 440 may include the same material as that of the first interlayer insulating film 410 or may include a different material from that of the first interlayer insulating film 410.

The (1_1)-st wiring line L11, the (1_2)-nd wiring line L12, and the (1_3)-rd wiring line L13 may be disposed within the second interlayer insulating film 420. The third connection line L3 may be disposed within the fourth interlayer insulating film 440.

Along the third direction DR3, the shielding layer SL may be spaced apart from the (1_1)-st wiring line L11, the (1_2)-nd wiring line L12, and the (1_3)-rd wiring line L13. Along the third direction DR3, the shielding layers SL may be respectively disposed between the (1_1)-st wiring line L11, the (1_2)-nd wiring line L12, and the (1_3)-rd wiring line L13 and the third connection line L3.

A first connection via 413 and a second connection via 414 may be formed within at least a portion of the first interlayer insulating film 410. The first connection via 413 and the second connection via 414 may extend through at least a portion of the first interlayer insulating film 410.

The first connection via 413 may electrically connect the first electrode layer 4121 and the first capacitor C10 to each other. The second connection via 414 may electrically connect the second electrode layer 4123 and the first capacitor C10 to each other.

Along the third direction DR3, the first capacitor C10 may be disposed on the electrode structure 412.

Each of the (1_1)-st wiring line L11, the (1_2)-nd wiring line L12, the (1_3)-rd wiring line L13, the third connection line L3, the first connection via 413, and the second connection via 414 may include metal or metal nitride. However, the subject matter of the present disclosure is not limited thereto. For example, copper, tungsten, aluminum, ruthenium, platinum, titanium, and tantalum may be used as the metal, and tungsten nitride, tantalum nitride, or titanium nitride may be used as the metal nitride.

Referring to FIG. 10, the electrode structure 412 may constitute a second capacitor structure LST2. For example, the first capacitor structure may be a MIM capacitor (Metal-Insulator-Metal capacitor). Furthermore, the wiring lines L11, L12, and L13 of the first capacitor C10 and the interlayer insulating film 420 may constitute a third capacitor structure. The third capacitor structure may constitute a vertical natural capacitor (VNCAP).

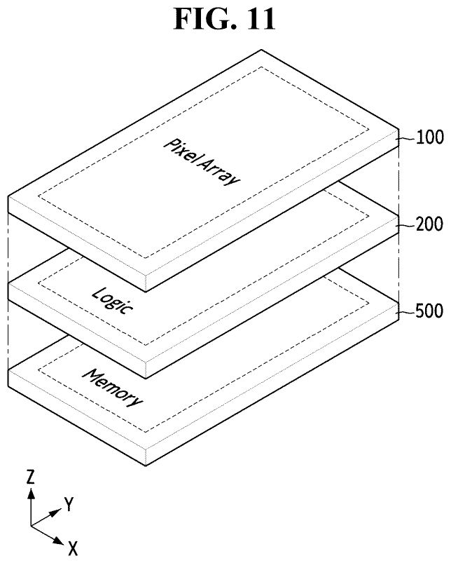

FIG. 11 is a diagram showing an example of a schematic layout of an image sensor. For convenience of description, the description will focus on differences thereof from those described above using FIGS. 1 to 10.

Referring to FIG. 11, the image sensor further includes a third substrate structure 500. The first substrate structure 100, the second substrate structure 200, and the third substrate structure 500 may be sequentially stacked along the third direction Z. The third substrate structure 500 may be disposed under the second substrate structure 200. That is, the second substrate structure 200 may be disposed between the first substrate structure 100 and the third substrate structure 500.

The third substrate structure 500 may include a memory device. The third substrate structure 500 may include, for example, a volatile memory device such as DRAM or SRAM. The third substrate structure 500 may receive signals from the first substrate structure 100 and the second substrate structure 200 and process the signals through the memory device. That is, the image sensor further including the third substrate structure 500 may correspond to a 3-stack image sensor.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. An image sensor comprising:
a pixel; and
a comparator circuit configured to generate a comparison signal based on a ramp signal and based on a pixel signal received from the pixel,
wherein the comparator circuit includes:
a comparator including a first input node configured to receive the ramp signal and the pixel signal and a second input node configured to receive a reference signal,
a first capacitor connected to the first input node, and
a second capacitor connected to the second input node,
wherein a distance from the first capacitor to the comparator is shorter than a distance from the second capacitor to the comparator in a first direction in a layout in a plan view.

2. The image sensor of claim 1, wherein a distance from the first input node to the first capacitor in the first direction in the layout in the plan view is shorter than a distance from the second input node to the second capacitor in the first direction in the layout in the plan view.

3. The image sensor of claim 1, wherein the comparator circuit is configured to output a comparison result of comparing a difference between the ramp signal and the pixel signal with the reference signal.

4. The image sensor of claim 1, wherein the first capacitor includes:
a (1_1)-st capacitor having a first end connected to the first input node and a second end configured to receive the ramp signal; and
a (1_2)-nd capacitor having a first end connected to the first input node and a second end configured to receive the pixel signal,
wherein the second capacitor includes (2_1)-st and (2_2)-nd capacitors connected in parallel with each other, wherein each of the (2_1)-st and the (2_2)-nd capacitors has a first end connected to the second input node, and a second end configured to receive the reference signal.

5. The image sensor of claim 4, wherein a first connection line is configured to provide the ramp signal to the (1_1)-st capacitor,
wherein a second connection line is configured to provide the pixel signal to the (1_2)-nd capacitor,
wherein a third connection line is configured to provide the reference signal from the second capacitor to the second input node.

6. The image sensor of claim 5, wherein the first and second connection lines are disposed on the second capacitor,
wherein the third connection line is disposed on the first capacitor.

7. The image sensor of claim 5, wherein shielding layers are respectively interposed between the first connection line and the (2_1)-st capacitor, between the second connection line and the (2_2)-nd capacitor, and between the third connection line and the (1_2)-nd capacitor.

8. The image sensor of claim 1, wherein the comparator circuit further includes:
a third capacitor having a first end connected to a first node between the first capacitor and the first input node, and a second end connected to a ground; and
a fourth capacitor having a first end connected to a second node between the second capacitor and the second input node, and a second end connected to the ground.

9. The image sensor of claim 1, wherein the comparator circuit further includes:
a fifth capacitor having a first end connected to the first input node, and a second end connected to a third node between the first input node and a first output node of the comparator circuit; and
a sixth capacitor having a first end connected to the second input node, and a second end connected to a fourth node between the second input node and a second output node of the comparator circuit.

10. The image sensor of claim 9, wherein the comparator circuit includes:
a seventh capacitor having a first end connected to a fifth node between the first output node and the third node, and a second end connected to a ground; and
an eighth capacitor having a first end connected to a sixth node between the second output node and the fourth node, and a second end connected to the ground.

11. A semiconductor device comprising:
a pixel array structure comprising a plurality of pixels; and
a first capacitor structure configured to generate a comparison signal based on a first signal and based on a second signal received from the pixels,
wherein the first capacitor structure includes
a comparator configured to receive the first and second signals via a first input node and to receive a third signal different from the first and second signals via a second input node,
a first sampling capacitor connected to the first input node,
a second sampling capacitor connected to the second input node,
a first capacitor connected to a first node between the first sampling capacitor and the first input node, and
a second capacitor connected to a second node between the second sampling capacitor and the second input node,
wherein a capacitance of the first capacitor is different from a capacitance of the second capacitor.

12. The semiconductor device of claim 11, wherein the capacitance of the first capacitor is smaller than the capacitance of the second capacitor.

13. The semiconductor device of claim 11, wherein the first sampling capacitor includes:
a (1_1)-st sampling capacitor having a first end connected to the first input node and a second end configured to receive the first signal; and
a (1_2)-nd sampling capacitor having a first end connected to the first input node and a second end configured to receive the second signal,
wherein the second sampling capacitor includes (2_1)-st and (2_2)-nd sampling capacitors connected in parallel with each other, wherein a first end of each of the (2_1)-st and the (2_2)-nd sampling capacitors is connected to the second input node, and a second end of each thereof is configured to receive the third signal.

14. The semiconductor device of claim 11, further comprising:
a substrate; and
a second capacitor structure disposed on the substate and including a gate insulating film and a gate electrode,
wherein the first capacitor structure is disposed on the second capacitor structure.

15. The semiconductor device of claim 14, further comprising:
a first connection via electrically connecting the substrate and the first capacitor structure to each other; and
a second connection via electrically connecting the gate electrode and the first capacitor structure to each other.

16. The semiconductor device of claim 11, further comprising:
a substrate; and
a second capacitor structure disposed on the substrate, wherein the second capacitor structure includes a first electrode layer, a second electrode layer disposed on the first electrode layer, and a dielectric layer between the first and second electrode layers,
wherein the first capacitor structure is disposed on the second capacitor structure.

17. The semiconductor device of claim 16, further comprising:
a first connection via electrically connecting the first electrode layer and the first capacitor structure to each other; and
a second connection via electrically connecting the second electrode layer and the first capacitor structure to each other.

18. An image sensor comprising:
a pixel array comprising a plurality of pixels; and
a comparator circuit structure including a plurality of capacitor circuits electrically connected to the pixel array,
wherein the plurality of capacitor circuits include first and second capacitor circuits configured to receive first and second pixel signals, respectively, from the pixel array,
wherein the first capacitor circuit includes
a first comparator circuit configured to receive a ramp signal and the first pixel signal, via a first input node thereof, and to receive a first reference signal via a second input node thereof,
a first sampling capacitor connected to the first input node, and
a second sampling capacitor connected to the second input node,
wherein a distance from the first input node of the first comparator circuit to the first sampling capacitor in a first direction in a layout in a plan view is shorter than a distance from the second input node of the first comparator circuit to the second sampling capacitor in the first direction in the layout in the plan view,
wherein the second capacitor circuit includes:
a second comparator circuit configured to receive the ramp signal and the second pixel signal via a third input node thereof, and to receive a second reference signal via a fourth input node thereof,
a third sampling capacitor connected to the third input node, and
a fourth sampling capacitor connected to the fourth input node,
wherein a distance from the third input node of the second comparator circuit to the third sampling capacitor in the first direction in the layout in the plan view is shorter than a distance from the fourth input node of the second comparator circuit to the fourth sampling capacitor in the first direction in the layout in the plan view.

19. The image sensor of claim 18, wherein the first sampling capacitor includes:
a (1_1)-st sampling capacitor having a first end connected to the first input node and a second end configured to receive the ramp signal; and
a (1_2)-nd sampling capacitor having a first end connected to the first input node and a second end configured to receive the first pixel signal,
wherein the second sampling capacitor includes (2_1)-st and (2_2)-nd sampling capacitors connected in parallel with each other, wherein a first end of each of the (2_1)-st and the (2_2)-nd sampling capacitors is connected to the second input node, and a second end of each thereof is configured to receive the first reference signal.

20. The image sensor of claim 18, wherein the third sampling capacitor includes:
a (3_1)-st sampling capacitor having a first end connected to the third input node and a second end configured to receive the ramp signal; and
a (3_2)-nd sampling capacitor having a first end connected to the third input node and a second end configured to receive the second pixel signal,
wherein the fourth sampling capacitor includes (4_1)-st and (4_2)-nd sampling capacitors connected in parallel with each other, wherein a first end of each of the (4_1)-st and (4_2)-nd sampling capacitors is connected to the fourth input node, and a second end of each of the (4_1)-st and (4_2)-nd sampling capacitors is configured to receive the second reference signal.
